(19) United States
(12) Patent Application Publication
(10) Pub. No.: US 2005/0258491 A1
(43) Pub. Date: Nov. 24, 2005

(54) Threshold and flatband voltage stabilization layer for field effect transistors with high permittivity gate oxides

(75) Inventors: Nestor A. Bojarczuk JR., Poughkeepsie, NY (US); Eduard A. Cartier, New York, NY (US); Martin M. Frank, New York, NY (US); Evgeni Gousev, Mahopac, NY (US); Supratik Guha, Chappaqua, NY (US); Vijay Narayanan, New York, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, ARMONK, NY (US)

(21) Appl. No.: 10/845,719

(22) Filed: May 14, 2004

(51) Int. Cl. H01L 29/76

(52) U.S. Cl. 257/369

(57) ABSTRACT

An insulating interlayer for use in complementary metal oxide semiconductor (CMOS) that prevents unwanted shifts in threshold voltage and flatband voltage is provided. The insulating interlayer is located between a gate dielectric having a dielectric constant of greater than 4.0 and a Si-containing gate conductor. The insulating interlayer of the present invention is any metal nitride, that optionally may include oxygen, that is capable of stabilizing the threshold and flatband voltages. In a preferred embodiment, the insulating interlayer is aluminum nitride or aluminum oxynitride and the gate dielectric is hafnium oxide, hafnium silicate or hafnium silicon oxynitride. The present invention is particularly useful in stabilizing the threshold and flatband voltage of p-type field effect transistors.

### FIELD OF THE INVENTION

The present invention generally relates to a semiconductor device, and more particularly to a complementary metal oxide semiconductor (CMOS) structure that includes an interlayer between a Si-containing gate electrode and a high k gate dielectric that is capable of stabilizing the threshold voltage and flatband voltage of the structure.

### BACKGROUND OF THE INVENTION

In standard silicon complementary metal oxide semiconductor (CMOS) technology, p-type field effect transistors (pFET) use a boron (or other acceptor) doped p-type polysilicon layer as a gate electrode that is deposited on top of a silicon dioxide or silicon oxynitride gate oxide layer. The gate voltage is applied through this polysilicon layer to create an inversion channel in the n-type silicon underneath the gate oxide layer.

For a pFET to work properly, the inversion should begin occurring at slightly negative voltages applied to the polysilicon (poly-Si) gate electrode. This occurs as a consequence of the band alignment for the gate stack structure as depicted in FIG. 1. Specifically, FIG. 1 shows the approximate band alignment across a poly-Si/gate oxide gate stack in a typical pFET at zero gate bias. In FIG. 1, E_{c}, Eᵥ and E_{f} are the conduction band edge, valence band edge and the Fermi level in the silicon, respectively. The poly-Si/gate oxide/n-type silicon stack forms a capacitor that swings into inversion at around 0 V and into accumulation around +1 V (depending on the substrate doping). The threshold voltage Vₜ, which can be interpreted as the voltage at which the inversion starts occurring, is therefore approximately 0 V and the flatband voltage, which is the voltage just beyond which the capacitor starts to swing into accumulation, is approximately +1 V. The exact values of the threshold and flatband voltages have a dependence on the doping level in the silicon substrate, and can be varied somewhat by choosing an appropriate substrate doping level.

In future technology, silicon dioxide or silicon oxynitride dielectrics will be replaced with a gate material that has a higher dielectric constant. These materials are known as “high k” materials with the term “high k” denoting an insulating materials whose dielectric constant is greater than 4.0, preferably greater than about 7.0. The dielectric constants mentioned herein are relative to a vacuum unless otherwise specified. Of the various possibilities, hafnium oxide, hafnium silicate, or hafnium silicon oxynitride may be the most suitable replacement candidates for conventional gate dielectrics due to their excellent thermal stability at high temperatures.

Unfortunately, when p-type field effect transistors are fabricated using a dielectric such as hafnium oxide or hafnium silicate, it is a well known problem that the flatband voltage of the device is shifted from its ideal position of close to about +1 V, to about 0±300 mV. This shift in flatband voltage is published in C. Hobbs et al., entitled “Fermi Level Pinning at the Poly-Si/Metal Oxide Interface”, 2003 Symposium on VLSI Technology Digest of Technical Papers. Consequently, the threshold voltage of the device is shifted to approximately −1 V. This threshold voltage shift is believed to be a consequence of an intimate interaction between the Hf-based gate oxide layer and the polysilicon layer. One model (See, for example, C. Hobbs, et al., ibid.) speculates that such an interaction causes an increase in the density of states in the silicon band gap at the polysilicon-gate oxide interface, leading to “Fermi level pinning”. The threshold voltage therefore is not in the “right” place, i.e., it is too high for a useable CMOS (complementary metal oxide semiconductor) technology.

One possible solution to the above problem of threshold voltage shifting is by substrate engineering in which channel implants can be used to shift thresholds. Although substrate engineering is one possible means to stabilize threshold voltage shift, it can do so to a limited extent, which is inadequate for FETs that include a gate stack comprising a poly-Si gate electrode and a hafnium-containing high dielectric constant gate dielectric.

In view of the above mentioned problem in threshold voltage and flatband voltage shift, it has been nearly impossible to develop a polysilicon/high k gate dielectric CMOS technology that is capable of stabilizing the threshold and flatband voltage for such FETs. As such, a method and structure that is capable of stabilizing the threshold voltage and flatband voltage of FETs containing a poly-Si/high k dielectric gate stack is needed.

### SUMMARY OF THE INVENTION

The present invention solves the above problem of threshold and flatband voltage variation by incorporating an insulating interlayer between a high k gate dielectric and a Si-containing gate conductor. The insulating interlayer employed in the present invention is any insulating material that is capable of preventing interaction between the high k gate dielectric and the Si-containing gate conductor by spatial separation. Moreover, the insulating interlayer employed in the present invention has a sufficiently high dielectric constant (on the order of about 4.0 or greater) such that there is a minimal decrease in gate capacitance (due to series capacitance effect) with its addition. The insulating interlayer employed in the present invention may dissociate, at least partially, to provide a supply of p-type dopants in the near interfacial layer to ensure p-type behavior of the near interfacial Si-containing layer and it can prevent outdiffiusion of impurities from the high k gate dielectric into the Si-containing gate conductor and vice versa.

It should be noted that the insulating interlayer of the present invention is a chemical interlayer that prevents interaction between the high k gate dielectric and the Si-containing gate electrode. The interlayer of the present invention is substantially non-reactive with the underlying high k gate dielectric therefore it does not react with the high k gate dielectric forming a silicide. The interlayer of the present invention is also non-reactive with the above lying Si-containing gate conductor.

Another characteristic feature of the inventive insulating interlayer is that it is chemically stable so that silicon cannot reduce it. In cases in which some dissociation of the inventive interlayer may occur, the inventive interlayer should not be an n-type dopant to silicon. Rather, the inventive interlayer can be either a p-type dopant or a neutral dopant so that device performance is not adversely affected. Also, the insulating interlayer employed in the present invention should be a refractory compound that is able to withstand high temperatures (of approximately 1000° C., typical of standard CMOS processing).

Insulating materials that fit the above mentioned criteria and are thus employed as the insulating interlayer of the present invention include any insulating metal nitride, i.e., metal nitride-containing material, that may optional include oxygen therein. Examples of insulating interlayers include, but are not limited to: aluminum nitride (AlN), aluminum oxynitride (AlOₓN_{y}), boron nitride (BN), boron oxynitride (BOₓN_{y}), gallium nitride (GaN), gallium oxynitride (GaON), indium nitride (InN), indium oxynitride (InON) and combinations thereof. The insulating interlayer is a thin interlayer located between the high k gate dielectric and the Si-containing gate electrode. Typically, the insulating interlayer has a thickness in the range from about 1 to about 25 Å, with a thickness from about 2 to about 15 Å being more typical.

Some of the inventive interlayer compounds have been used as gate oxides themselves in the past (see for instance, L-Å. Ragnarsson, et al., “Physical and electrical properties of reactive molecular beam deposited aluminum nitride in metal-oxide-silicon structures”, J. Applied Physics, 93 (2003) 3912-3919; S. Guha, et al., “High temperature stability of Al₂O₃ dielectrics on Si: Interfacial metal diffusion and mobility degradation”, Applied Physics Letters, 81 (2002) 2956-2958; S. Skordas, et al., “Low temperature metal organic chemical vapor deposition of aluminum oxide thin films for advanced CMOS gate dielectric applications, in Silicon Materials—Processing, Characterization, and Reliability”, edited by J. L. Veteran, P. S. Ho, D. O'Meara, V. Misra, 2002, p. 36; D. A. Buchanan, et al., “80 nm poly-silicon gated n-FETs with ultra-thin Al₂O₃ gate dielectric for ULSI applications”, IEDM Technical Digest (2000) 223-226)) or as an etch stop layer (see, for example, C. S. Park, et al., “In Integrable Dual Metal Gate CMOS Process using Ultrathin Aluminum Nitride Buffer Layer”, IEEE Electron Dev. Lett. 24 (2003) 298-300)). Despite these disclosures, the applicants of the present application are unaware of any prior art in which an insulating metal nitride, which optionally can include oxygen, is used to prevent intimate interaction between a high k dielectric and a Si-containing gate electrode for the purpose of stabilizing the threshold voltage and flatband voltage which typically shifts during operation (may be use fabrication instead, as it is really not an operation induced issue) when such an insulating interlayer is not present.

Aluminum oxide (Al₂O₃) has been previously reported to be used as a material layer in between hafnium oxide and polysilicon in order to attempt to improve the uniformity of electrical properties. See, for example, D. C. Gilmer, et al., “Compatibility of Silicon Gates with Hafnium-based Gate Dielectrics”, Microelectronic Engineering, Vol. 69, Issues 2-4, September 2003, pp. 138-144. Despite this teaching, the applicants have determined that when an Al₂O₂ layer is interposed between hafnium silicate and polysilicon, there is no beneficial improvement in the threshold voltage and flatband voltage shift. These finding will be provided in greater detail hereinbelow.

Co-pending and Co-assigned U.S. patent application Publication US2002/0090773 A1 describes a field effect transistor structure that includes a substrate having a source region, a drain region and a channel region therebetween, an insulating disposed over the channel region and a gate electrode disposed over the insulating layer. The insulating layer can include aluminum nitride alone, or aluminum nitride disposed over or underneath aluminum oxide, silicon dioxide, or silicon nitride. Aluminum nitride is used in this disclosure to provide a device that has a low leakage current.

Co-pending and Co-assigned U.S. patent application Publication US2002/0190302 A1 describes a diffusion barrier for a field effect transistor which includes an insulating layer as a gate dielectric that includes nitrogen. The nitrogen can be introduced by infusion, nitridation or deposition of a nitrogen compound over an insulating layer.

None of the art cited herein discloses the use of an insulating interlayer between a high k dielectric and a Si-containing electrode as a means for stabilizing the threshold voltage and flatband voltage of a transistor to a targeted value.

In broad terms, the present invention provides a complementary metal oxide semiconductor (CMOS) structure that includes a semiconductor substrate having source and drain diffusion regions located therein, the source and drain diffusion regions are separated by a device channel; and a gate stack located on top of the device channel, said gate stack comprising a high k gate dielectric, an insulating interlayer and a silicon-containing gate conductor, said insulating interlayer is located between said high k gate dielectric and said Si-containing gate conductor and is capable of stabilizing the structure's threshold voltage and flatband voltage to a targeted value.

In one highly preferred embodiment of the present invention, a CMOS structure is provided that includes a semiconductor substrate having source and drain diffusion regions located therein, said source and drain diffusion regions are separated by a device channel; and a gate stack located on top of said device channel, said gate stack comprising a hafnium-containing high k gate dielectric, an aluminum nitride-containing insulating interlayer and a Si-containing gate conductor, said aluminum nitride-containing insulating interlayer is located between said hafnium-containing high k gate dielectric and said Si-containing gate conductor and is capable of stabilizing the structure's threshold voltage and flatband voltage to a targeted value.

In another aspect of the present invention, a method of forming a complementary metal oxide semiconductor (CMOS) structure having improved threshold voltage and flatband voltage stability is provided. The method includes the steps of providing a gate stack comprising a high k gate dielectric, an insulating interlayer and a Si-containing gate conductor on a semiconductor substrate, said insulating interlayer is located between said high k gate dielectric and said Si-containing gate conductor; and applying a bias by any known technique to said gate stack, whereby said insulating interlayer stabilizes the structure's threshold voltage and flatband voltage to a targeted value.

### BRIEF DESCRIPTION OF THE DRAWINGS

FIG. 1 is a schematic showing approximate band alignment across a prior art gate stack in a typical pFET at zero gate bias, V_{g}=0 V. The quantities E_{c} and Eᵥ denote the conduction and the valence band edge, respectively, in the silicon substrate and in the polysilicon gate. E_{f} denotes the Fermi level position (dotted line) in the silicon substrate and in the polysilicon gate at zero gate bias.

FIG. 2 is a pictorial representation (through a cross sectional view) of the inventive CMOS structure that includes a threshold voltage stabilization interlayer of the present invention located between a high k gate dielectric and a poly-Si gate electrode.

FIGS. 3A-3D are graphs showing the capacitance-voltage curves for a set of gate stacks with boron doped polysilicon gates on gate stacks containing a 0.6 to 1.3 nm AlN threshold stabilization interlayer on a 4 nm Hf silicate/Si substrate. Temperatures for AlN deposition were 300° C. for FIGS. 3B and 3D and 600° C. for FIGS. 3A and 3C. Flatband voltages (V_{fb}) are in the range of 0.6 to 0.76 V. The SiO₂-equivalnet oxide thickness (EOT) varies from 2.9 to 4.8 nm depending on AlN thickness and HF silicate thickness. The ‘center’ to ‘edge’ variation in EOT is due to a variation in Hf-silicate thickness across the 8 inch wafers used in these experiments.

FIG. 4 is a comparison of capacitance-voltage curve for three types of pFET devices. The solid lines show an oxide control device with a 2.5 nm thick. SiO2 gate oxide. The open circles show a pFET with a 3 nm thick Hf-silicate layer on a 1 nm SiO₂ interfacial oxide as the gate dielectric and the solid symbols show a pFET with an AlN threshold stabilization layer between Hf-silicate and a boron-doped polysilicon gate electrode.

FIGS. 5A-5B show typical split CV (FIG. 5A) and drain current versus gate voltage (I_{d}-V_{g}) characteristics (FIG. 5B) for typical pFET devices with a 3 nm thick Hf-silicate layer and a 0.9 to 1.2 nm thick AlN cap layer. The I_{d}-V_{g} curves were measured at a drain to source voltage of 100 mV. In each case, nine devices were measured across an 8 inch wafer.

FIG. 6 is a plot showing the mobility variation as a function of inversion charge density for pFET devices with Hf-silicate and Hf-silicate with a ALN cap layer.

FIG. 7 is a plot showing SiO₂-equivalent oxide thickness (EOT) of Al₂O₃ cap layers on hafnium silicate (20%) as a function of ALD Al₂O₃ deposition cycles.

FIG. 8 is a plot showing capacitance voltage characteristics of various nFETs reported in the comparative example.

FIG. 9 is a plot showing capacitance voltage characteristics of various pFETs reported in the comparative example.

FIG. 10 is a plot showing flatband voltages and threshold voltages extracted from the data shown in FIGS. 8 and 9.

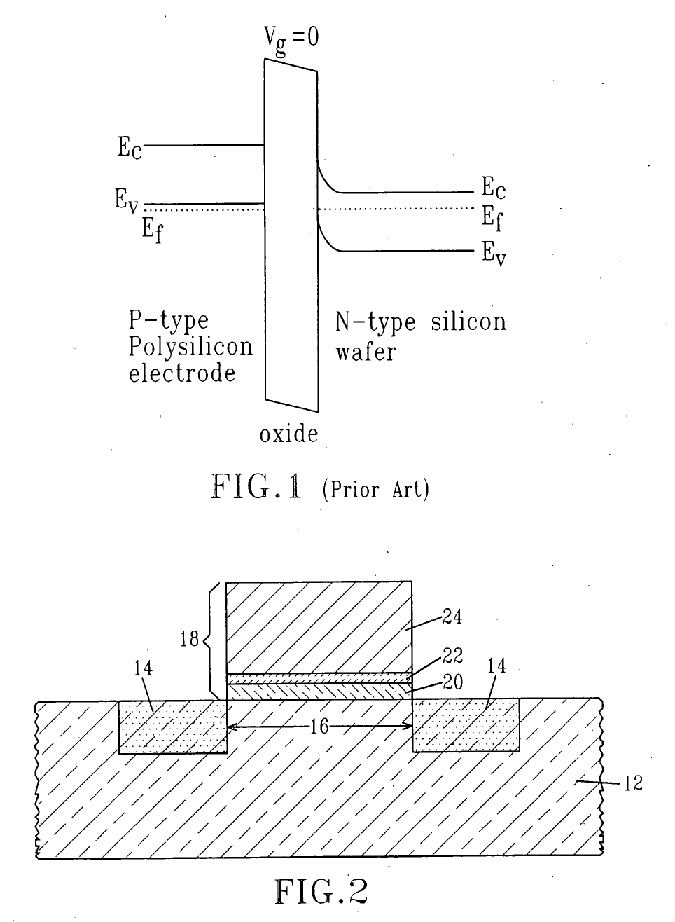

### DETAILED DESCRIPTION OF THE INVENTION

The present invention, which provides a CMOS structure that includes an insulating metal nitride-containing interlayer between a Si-containing gate electrode and a high k gate dielectric that is capable of stabilizing the threshold voltage and flatband voltage of the structure, and a method of fabricating the same will now be described in more detail. The term “metal nitride-containing interlayer” includes metal nitride and metal oxynitride layers. It is noted that in FIG. 2, the structure is not drawn to scale. Also, although a single FET is shown on a semiconductor substrate, the present invention contemplates a plurality of FETs on the surface of the same substrate. The neighboring FETs can be isolated from each other by isolation regions, which are not shown in FIG. 2. Also spacers can be formed on the sidewalls of the FET structure shown in FIG. 2.

Reference is made to FIG. 2, which is a pictorial representation (through a cross sectional view) showing the CMOS structure 10 of the present invention. Specifically, the CMOS structure 10 includes a semiconductor substrate 12, source/drain diffusion regions 14 located in the semiconductor substrate 12, which are separated from each other by device channel 16, and a gate stack 18 comprising a high k dielectric 20 located atop the device channel 16, an insulating interlayer 22 located atop the high k dielectric 20 and a Si-containing gate conductor 24 located atop the insulating interlayer 22.

The various components of the structure shown in FIG. 2 as well as the process that can be used in forming the same will now be described in greater detail.

The structure shown in FIG. 2 is made by first providing blanket layers of the high k gate dielectric 20, the insulating interlayer 22 and the Si-containing gate conductor 24 on a surface of the semiconductor substrate 12. In accordance with the present invention, the insulating interlayer 22 is located between the high gate dielectric 20 and the Si-containing gate conductor 24.

The semiconductor substrate 12 employed in the present invention comprises any semiconducting material including, but not limited to: Si, Ge, SiGe, SiC, SiGeC, Ga, GaAs, InAs, InP and all other III/V or II/VI compound semiconductors. Semiconductor substrate 12 may also comprise an organic semiconductor or a layered semiconductor such as Si/SiGe, a silicon-on-insulator (SOI) or a SiGe-on-insulator (SGOI). In some embodiments of the present invention, it is preferred that the semiconductor substrate 12 be composed of a Si-containing semiconductor material, i.e., a semiconductor material that includes silicon. The semiconductor substrate 12 may be doped, undoped or contain doped and undoped regions therein.

The semiconductor substrate 12 may also include a first doped (n- or p-) region, and a second doped (n- or p-) region. For clarity, the doped regions are not specifically shown in the drawing of the present application. The first doped region and the second doped region may be the same, or they may have different conductivities and/or doping concentrations. These doped regions are known as “wells”.

At least one isolation region (not shown) is then typically formed into the semiconductor substrate 12. The isolation region may be a trench isolation region or a field oxide isolation region. The trench isolation region is formed utilizing a conventional trench isolation process well known to those skilled in the art. For example, lithography, etching and filling of the trench with a trench dielectric may be used in forming the trench isolation region. Optionally, a liner may be formed in the trench prior to trench fill, a densification step may be performed after the trench fill and a planarization process may follow the trench fill as well. The field oxide may be formed utilizing a so-called local oxidation of silicon process. Note that the at least one isolation region provides isolation between neighboring gate regions, typically required when the neighboring gates have opposite conductivities. The neighboring gate regions can have the same conductivity (i.e., both n- or p-type), or alternatively they can have different conductivities (i.e., one n-type and the other p-type).

After forming the at least one isolation region within the semiconductor substrate 12, a high k gate dielectric 20 is formed on a surface of the structure. The high k gate dielectric 20 can be formed by a thermal growth process such as, for example, oxidation, nitridation or oxynitridation. Alternatively, the high k gate dielectric 20 can be formed by a deposition process such as, for example, chemical vapor deposition (CVD), plasma-assisted CVD, metalorganic chemical vapor deposition (MOCVD), atomic layer deposition (ALD), evaporation, reactive sputtering, chemical solution deposition and other like deposition processes. The high k gate dielectric 20 may also be formed utilizing any combination of the above processes.

The high k gate dielectric 20 is comprised of an insulating material having a dielectric constant of greater than about 4.0, preferably greater than 7.0. Specifically, the high k gate dielectric 20 employed in the present invention includes, but not limited to: an oxide, nitride, oxynitride and/or silicate including metal silicates and nitrided metal silicates. In one embodiment, it is preferred that the gate dielectric 20 is comprised of an oxide such as, for example, HfO₂, ZrO₂, Al₂O₃, TiO₂, La₂O₃, SrTiO₃, LaAlO₃, Y₂O₃ and mixtures thereof. Highly preferred examples of gate dielectrics 20 include HfO₂, hafnium silicate and hafnium silicon oxynitride.

The physical thickness of the high k gate dielectric 20 may vary, but typically, the high k gate dielectric 20 has a thickness from about 0.5 to about 10 nm, with a thickness from about 0.5 to about 3 nm being more typical. It may be deposited above a thin (on the order of about 0.1 to about 1.5 nm) layer of silicon oxide or silicon oxynitride that is first deposited on the substrate.

Next, insulating interlayer 22 is formed atop the blanket layer of high k gate dielectric 20. As stated above, the insulating interlayer 22 employed in the present invention has at least one of the following characteristics: (i) it is capable of preventing interaction between the high k gate dielectric 20 and the Si-containing gate conductor 24 by spatial separation; (ii) it has a sufficiently high dielectric constant (on the order of about 4.0 or greater) such that there is a minimal decrease in gate capacitance (due to series capacitance effect) because of its addition; (iii) it may dissociate, at least partially, to provide a supply of p-type dopants in the near interfacial layer to ensure p-type behavior of the near interfacial Si-containing gate electrode material; (iv) it can prevent outdiffusion of atoms from the high k gate dielectric 20 into the Si-containing gate conductor 24; and (v) it can prevent later oxidation under the Si-containing gate conductor 24.

The insulating interlayer 22 of the present invention is a chemical interlayer that prevents interaction between the high k gate dielectric 20 and the Si-containing gate electrode 24. The interlayer 22 of the present invention is substantially non-reactive (there may be slight or partial decomposition, such as when its acts as a dopant source) with the underlying high k gate dielectric 20 therefore it does not react with the high k gate dielectric forming a silicide. Another characteristic feature of the inventive insulating interlayer 22 is that silicon cannot reduce the inventive insulating interlayer 22. In cases in which some dissociation of the inventive interlayer 22 may occur, the inventive interlayer 22 should be either a p-type dopant or a neutral dopant so that device performance is not adversely affected. Also, the insulating interlayer 22 employed in the present invention should be a refractory compound that is able to withstand high temperatures (of approximately 1000° C., typical of standard CMOS processing).

Insulating materials that fit the above-mentioned criteria and are thus employed as the insulating interlayer 22 of the present invention include any insulating metal nitride that may optional include oxygen therein. Examples of insulating interlayers include, but are not limited to: aluminum nitride (AlN), aluminum oxynitride (AlOₓN_{y}), boron nitride (BN), boron oxynitride (BOₓN_{y}), gallium nitride (GaN), gallium oxynitride (GaON), indium nitride (InN), indium oxynitride (InON) and combinations thereof. In one preferred embodiment of the present invention, the insulating interlayer 22 is AlN or AlOₓN_{y}.

The insulating interlayer 22 is a thin layer that typically has a thickness from about 1 to about 25 Å, with a thickness from about 2 to about 15 Å being more typical.

The insulating interlayer 22 can be formed by various deposition processes such as, for example, chemical vapor deposition (CVD), plasma-assisted CVD, atomic layer deposition (ALD) using aluminum and nitrogen-based precursors, physical vapor deposition or molecular beam deposition where the metal is evaporated along with a beam or ambient of atomic or molecular nitrogen (that may be optionally an excited species) and optionally oxygen, metalorganic chemical vapor deposition (MOCVD), atomic layer deposition, sputtering, and the like. Alternatively, the insulating interlayer 22 can be formed by thermal nitridation or oxynitridation of a previously deposited insulating metal layer. Alternatively, the oxynitride of the metal may be created by first depositing the metal nitride, followed by partial oxidation in a suitable oxygen environment to create and oxynitride.

One preferred method of forming the interlayer insulating layer 22 is by evaporating, under a high vacuum, Al from a standard Al effusion cell that is resistively heated, and using a nitrogen, or oxygen and nitrogen beams from commercial radio frequency (RF) atomic nitrogen or nitrogen and oxygen sources. For deposition of the nitride alone, a single RF nitrogen source suffices. For the oxynitride, a second RF source of oxygen may be used. Alternatively, the oxygen may be delivered simply as a molecular beam without an RF source. The process of evaporating under a high vacuum is described, for example, in U.S. Pat. No. 6,541,079, the entire content of which is incorporated herein by reference. The effusion cell typically has a temperature from about 1000° C.-1200° C. during the evaporation process. The evaporation process is typically performed using a RF source having a power from about 200-450 W and a flow rate from about 1-3 sccm. These numbers can also be widely varied from the stated bounds without problems. The substrate temperature is typically kept between 150° C. to 650° C. during deposition. Again, the deposition temperature can also be varied outside the stated ranges. Base vacuum chamber pressure is typically about 5×10⁻¹⁰ to 2×10⁻⁹ torr.

Notwithstanding the technique employed in forming the same, the insulating interlayer 22 formed in the present invention is a continuous and uniform layer that is present atop the high k gate dielectric 20. By “continuous”, it is meant that the insulating interlayer 22 contains no substantial breaks and/or voids therein; by “uniform” it is meant that the insulating interlayer 22 has nearly the same, as deposited, thickness across the structure. The insulating interlayer 22 may be amorphous meaning that it can lack a specific crystal structure. The insulating interlayer 22 may exist in other phases besides amorphous depending on the material used as well as the technique that is used in forming the same.

After forming the insulating interlayer 22, a blanket layer of a Si-containing material which becomes the Si-containing gate conductor 24 is formed on the insulating interlayer 22 utilizing a known deposition process such as, for example, physical vapor deposition, CVD or evaporation. The Si-containing material used in forming the gate conductor 24 includes Si or a SiGe alloy layer in either single crystal, polycrystalline or amorphous form. Combinations of the aforementioned Si-containing materials are also contemplated herein. The blanket layer of Si-containing material 24 may be doped or undoped. If doped, an in-situ doping deposition process may be employed in forming the same. Alternatively, a doped Si-containing layer can be formed by deposition, ion implantation and annealing. The doping of the Si-containing layer will shift the workfunction of the gate conductor formed. Illustrative examples of dopant ions include As, P, B, Sb, Bi, In, Al, Ga, or mixtures thereof. The thickness, i.e., height, of the Si-containing layer 24 deposited at this point of the present invention may vary depending on the deposition process employed. Typically, the Si-containing layer 24 has a vertical thickness from about 20 to about 180 nm, with a thickness from about 40 to about 150 nm being more typical.

In accordance with the present invention, the insulating interlayer 22 shows particular improvement in threshold voltage and flatband voltage stabilization when pFETs are formed. A pFET includes poly-Si that is doped with a p-type dopant such as boron.

After deposition of the blanket layer of Si-containing material 24, a dielectric cap layer (not shown) can be formed atop the blanket layer of Si-containing material 24 utilizing a deposition process such as, for example, physical vapor deposition or chemical vapor deposition. The dielectric cap layer may be an oxide, nitride, oxynitride or any combination thereof. The thickness, i.e., height, of the dielectric cap layer is from about 20 to about 180 nm, with a thickness from about 30 to about 140 nm being more typical.

The dielectric cap (if present), the blanket Si-containing layer 24, and optionally the insulating interlayer 22 and the high k gate dielectric 20 are then patterned by lithography and etching so as to provide a patterned gate stack 18. When a plurality of patterned gate stacks are formed, the gate stacks may have the same dimension, i.e., length, or they can have variable dimensions to improve device performance. Each patterned gate stack 18 at this point of the present invention includes at least the Si-containing gate conductor 24. The lithography step includes applying a photoresist to the upper surface of the blanket layered structure, exposing the photoresist to a desired pattern of radiation and developing the exposed photoresist utilizing a conventional resist developer. The pattern in the photoresist is then transferred to the structure utilizing one or more dry etching steps. In some embodiments, the patterned photoresist may be removed after the pattern has been transferred into one of the layers of the blanket layered structure. In other embodiments, the patterned photoresist is removed after etching has been completed.

Suitable dry etching processes that can be used in the present invention in forming the patterned gate stacks include, but are not limited to: reactive ion etching, ion beam etching, plasma etching or laser ablation. The dry etching process employed is typically, but not always, selective to the underlying high k gate dielectric 20 therefore this etching step does not typically remove the gate dielectric. In some embodiments, this etching step may however be used to remove portions of the gate dielectric 20 that are not protected by the material layers of the gate stack that were previously etched.

Next, at least one spacer (not shown) is typically, but not always, formed on exposed sidewalls of each patterned gate stack. The at least one spacer is comprised of an insulator such as an oxide, nitride, oxynitride and/or any combination thereof. The at least one spacer is formed by deposition and etching.

The width of the at least one spacer must be sufficiently wide such that the source and drain silicide contacts (to be subsequently formed) do not encroach underneath the edges of the gate stack. Typically, the source/drain silicide does not encroach underneath the edges of the gate stack when the at least one spacer has a width, as measured at the bottom, from about 20 to about 80 nm.

The gate stack 18 can also be passivated at this point of the present invention by subjecting the same to a thermal oxidation, nitridation or oxynitridation process. The passivation step forms a thin layer of passivating material about the gate stack. This step may be used instead or in conjunction with the previous step of spacer formation. When used with the spacer formation step, spacer formation occurs after the gate stack passivation process.

Source/drain diffusion regions 14 (with or without the spacers present) are then formed into the substrate. The source/drain diffusion regions 14 are formed utilizing ion implantation and an annealing step. The annealing step serves to activate the dopants that were implanted by the previous implant step. The conditions for the ion implantation and annealing are well known to those skilled in the art.

The source/drain diffusion regions 14 may also include extension implant regions which are formed prior to source/drain implantation using a conventional extension implant. The extension implant may be followed by an activation anneal, or alternatively the dopants implanted during the extension implant and the source/drain implant can be activated using the same activation anneal cycle. Halo implants are also contemplated herein.

Next, and if not previously removed, the exposed portion of the gate dielectric 20 is removed utilizing a chemical etching process that selectively removes the gate dielectric 20. This etching step stops on an upper surface of the semiconductor substrate 12. Although any chemical etchant may be used in removing the exposed portions of the gate dielectric 20, in one embodiment dilute hydrofluoric acid (DHF) is used.

Of the various combinations and embodiments described above, a particular preferred CMOS structure of the present invention is one in which the high k gate dielectric 20 is comprised of HfO₂, hafnium silicate or hafnium silicon oxynitride and the insulating interlayer 22 is comprised of AlN, which optionally may include some oxygen therein. The particularly preferred structure also includes a boron doped poly-Si gate conductor 24. Other variations and permutations of the particularly preferred structure are also contemplated herein and should not be excluded.

The above processing steps form the CMOS structure shown in FIG. 2. Further CMOS processing such as formation of silicided contacts (source/drain and gate) as well as formation of BEOL (back-end-of-the-line) interconnect levels with metal interconnects can be formed utilizing processing steps that are well known to those skilled in the art.

The following examples are provided for illustrative purposes to demonstrate the importance of using the inventive insulating interlayer.

### EXAMPLE 1

In this example, a Hf oxide or silicate layer was first grown on a silicon wafer that was pre-patterned with a field oxide. The Hf oxide and silicate was deposited using metalorganic chemical vapor deposition (MOCVD) and atomic layer chemical vapor deposition (ALCVD). The thicknesses of the Hf oxide and silicate layers were in the range of 2 nm to 4 nm and for the silicates, the composition was approximately HfₓSi_{y}O₄ with y/(x+y) being approximately 0.2-0.3. These oxides were deposited on a n-type silicon wafer which had a 0.3-1.2 nm thick silicon oxide or silicon oxynitride coating. The presence of this layer was strictly optional.

Following deposition of the Hf oxide and silicate, the wafers were loaded in an ultra-high vacuum deposition chamber for aluminum nitride deposition. Aluminum nitride was deposited by evaporating Al from a standard Al effusion cell that was resistively heated, and using a nitrogen beam from a commercial radio frequency atomic nitrogen source. The effusion cell had a temperature of 1000° C.-1200° C. during operation. The atomic nitrogen source was operated in the range of 200-450 W and a nitrogen flow rate of 1-3 sccm. The substrate temperature was kept between 150° C. to 650° C. during deposition. Base vacuum chamber pressure was about 5×10⁻¹⁰ to 2×10⁻⁹ torr.

During AlN deposition the pressure rose to the 1×10⁻⁵ torr range. Following the deposition of AlN layers with thicknesses between 0.5-2.0 nm, the substrates were taken out and approximately 150 nm thick amorphous silicon layers were deposited by chemical vapor deposition using standard procedures. The amorphous silicon was then ion implanted with boron and the dopants activated by annealing at approximately 950° C.-1000° C., again following standard semiconductor processing procedures. In some cases, forming gas anneals were performed for SiO₂/Si(100) interface state passivation. Capacitors were then made from these structures via lithography to define pad sizes that had approximate dimensions of the order of 10×10, 20×20, 50×50 and 100×100 square microns. The capacitor structures therefore were: B doped polysilicon/0.5-2 nm thick AlN/2-4 nm thick Hf silicate or HfO₂/0.3-1.2 nm SiO₂ or SiON (or thicker due to changes after deposition)/silicon(100) wafer. Also, standard device processing was carried out to fabricate standard pFETs with the same stack structure.

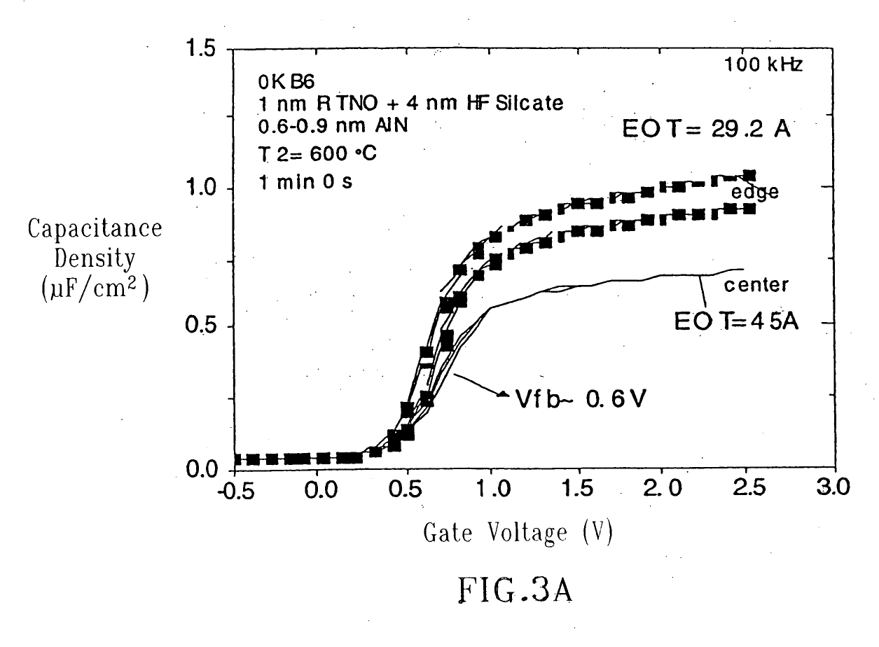

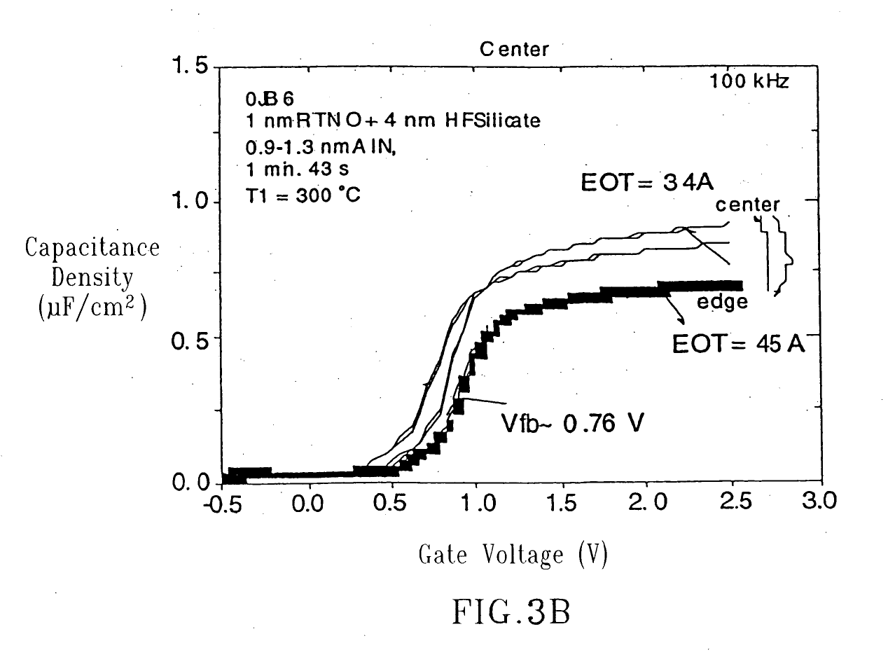

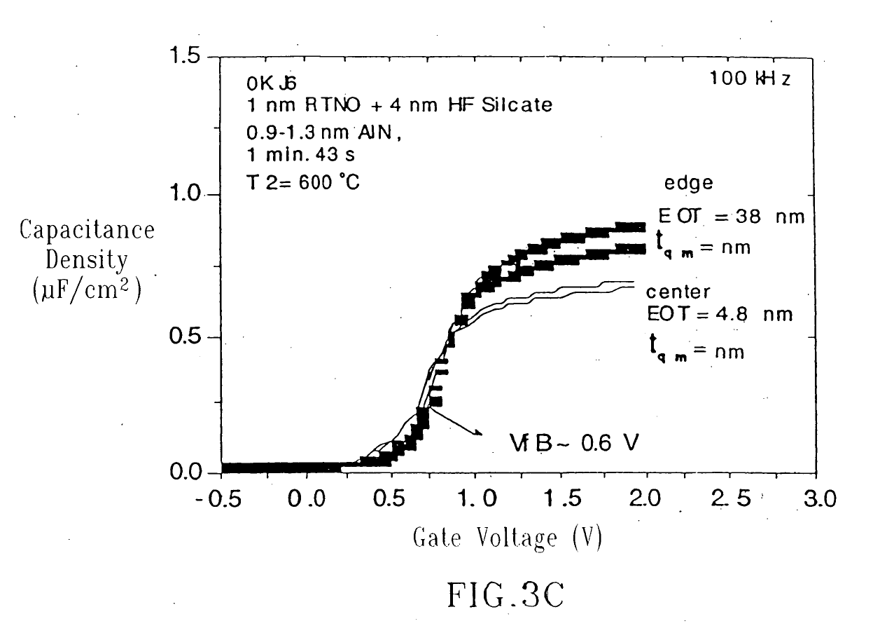

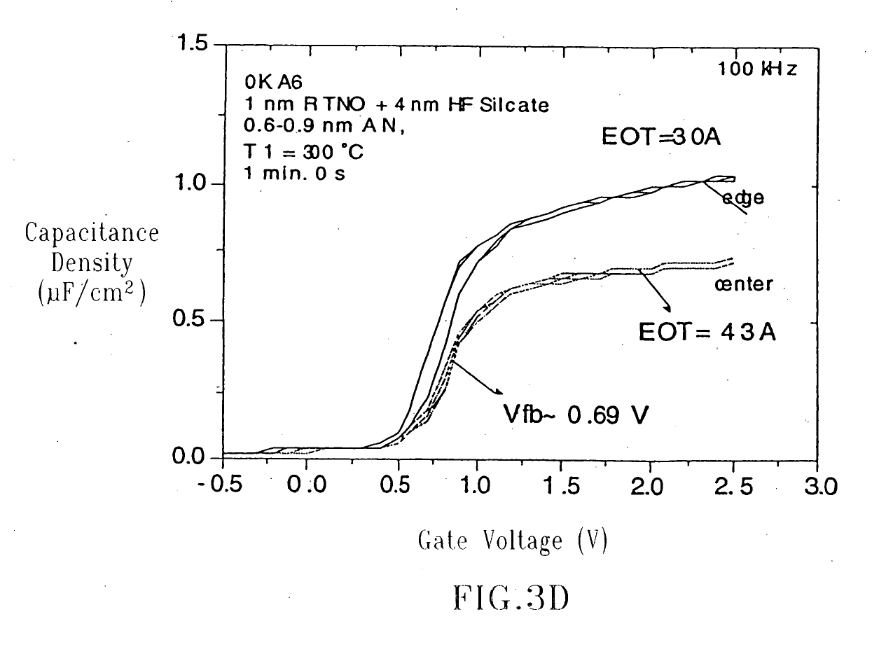

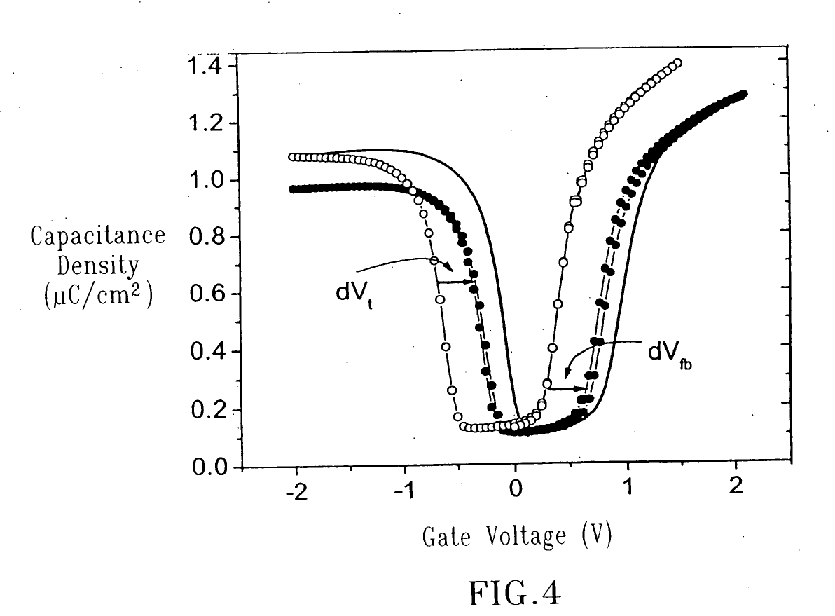

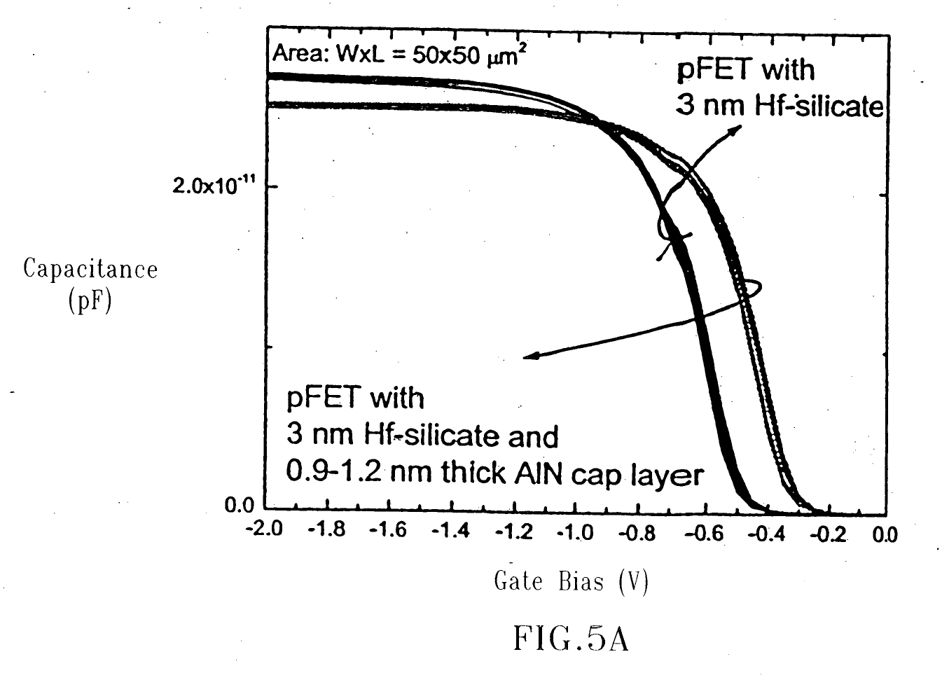

When the capacitors were tested electrically, they showed that the flatband voltage was within 200-400 mV of the ideal position at 1.0 V as shown in the measurement data of FIGS. 3A-3D and 4. The results in FIGS. 3A-3D were from a set of Hf silicate layers that were grown on transistors and have between 0.8 to 1.3 nm of AlN on top of them. When the AlN was exposed to the ambient some of it may oxidize resulting in an aluminum oxynitride layer. When the pFETs were tested, with gate stacks that possess a similar structure, again they showed that the threshold voltage of the device remained, as expected, closer to the ideal position (within 200-400 mV), as shown in the capacitance-voltage plots of pFETs in FIG. 4. As can be seen in FIG. 4, the device with Hf-silicate was strongly shifted towards a negative bias as compared to the control device. Also, and as indicated by the two horizontal lines, a substantial shift of the flatband (dV_{fb}) and threshold (dVₜ) voltages towards the control device was accomplished using an AlN cap layer.

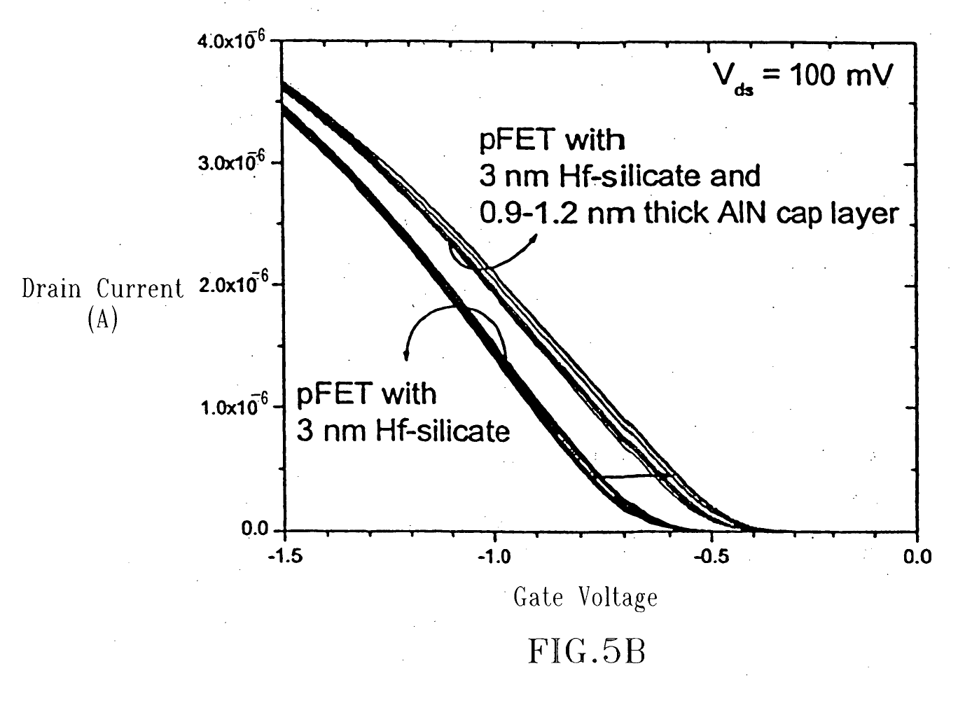

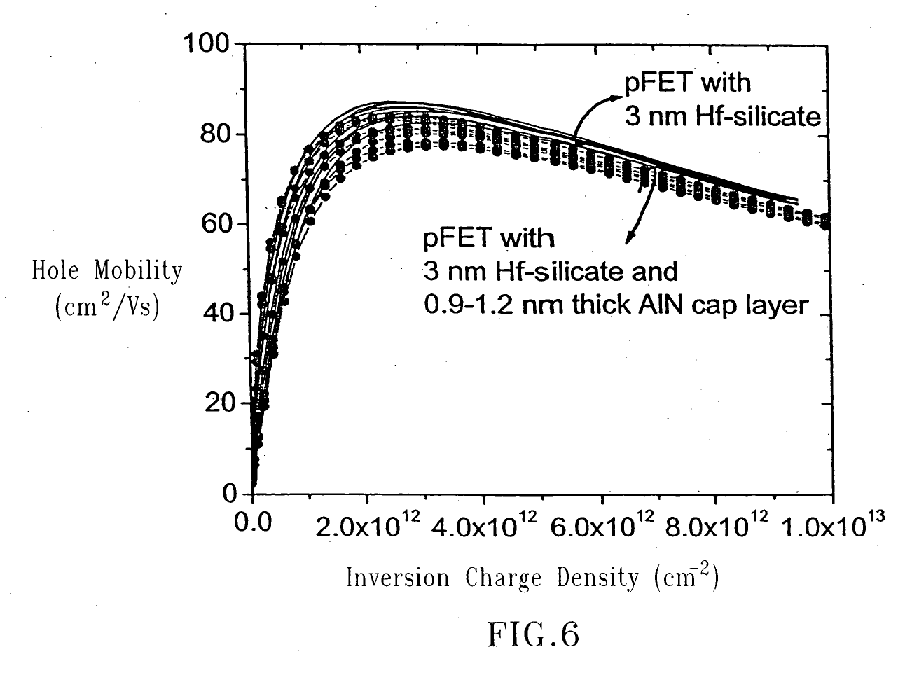

FIGS. 5A-5B show results from pFETs that were made using Hf silicate as the gate oxide. Again, an AlN threshold stabilization layer was used, and the threshold voltage was shifted towards zero. Transistor performance data for these pFETs is shown in FIG. 6. As shown in FIG. 6, no substantial degradation in the device performance was observed with the AlN cap layer.

In view of the above data, the presence of the AlN layer stabilized the threshold voltage close to the desirable value. Clearly, the AlN interlayers acted as an effective barrier between the Hf silicate or oxide and the polysilicon layer without compromising electrical performance.

Microstructural Issues:

Following deposition and after exposure to the ambient, some of the aluminum nitride can be oxidized since aluminum oxide is thermodynamically more stable than aluminum nitride. This will not affect the interlayer performance.

Since the aluminum nitride is deposited at a low temperature (<650° C.), it goes down as a uniform, contiguous layer, so that there is no substantial exposure of the Hf oxide or silicate layer to the polysilicon.

### COMPARATIVE EXAMPLE

The impact of atomic layer deposited (ALD) Al₂O₃ on the threshold and flatband voltage on FETs with hafnium silicate gate dielectrics was investigated. It is shown that no substantial changes in flatband and threshold voltage occur for Al₂O₃ thickness corresponding to 20 deposition cycles. This observation may in part be explained by Al₂O₃ growth inhibition, which may prevent the formation of physically closed caps in the thickness range of interest for device applications.

The high k dielectric used was MOCVD deposited hafnium silicate with silane as a Si source. The Al₂O₃ cap layers were deposited using Atomic Layer Deposition (ALD) with TMMA and H₂O as precursors. The cap thickness was controlled via the number TMMA/H₂O deposition cycles from 2 to 20 cycles. nFETs and pFETs were fabricated using a standard CMOS process flow and capacitance voltage measurements were used to measure the flatband and threshold voltages of the devices.

Results

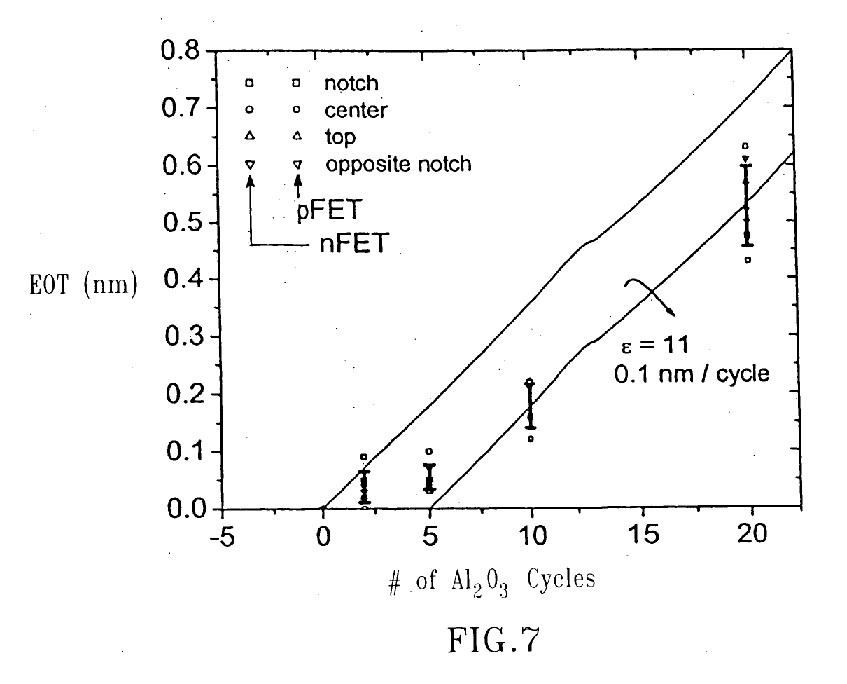

The main results of this study are summarized in FIGS. 7-10. FIG. 7 shows the thickness contribution of the Al₂O₃ cap layer (expressed in SiO₂ equivalent thickness numbers, EOT) measured on various locations on the 8 inch Si wafer. The EOT numbers were extracted from accumulation capacitance increase with respect to the capacitance of the uncapped hafnium silicate layer. As can be seen, after an initial growth inhibition, linear growth with approximately 0.1 nm of Al₂O₃ per cycle is observed. This suggests that the cap layers are likely not closed for less than 5 cycles. Closed caps are more likely formed after 10 and 20 cycles of Al₂O₃ deposition, as the growth rate is identical to that on thick Al₂O₃ layers.

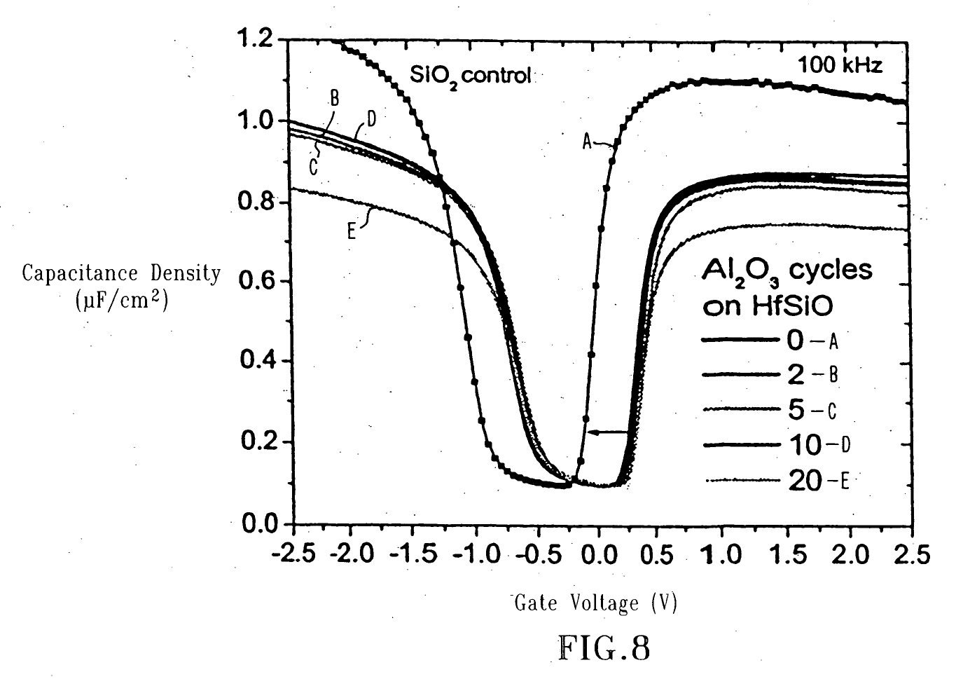

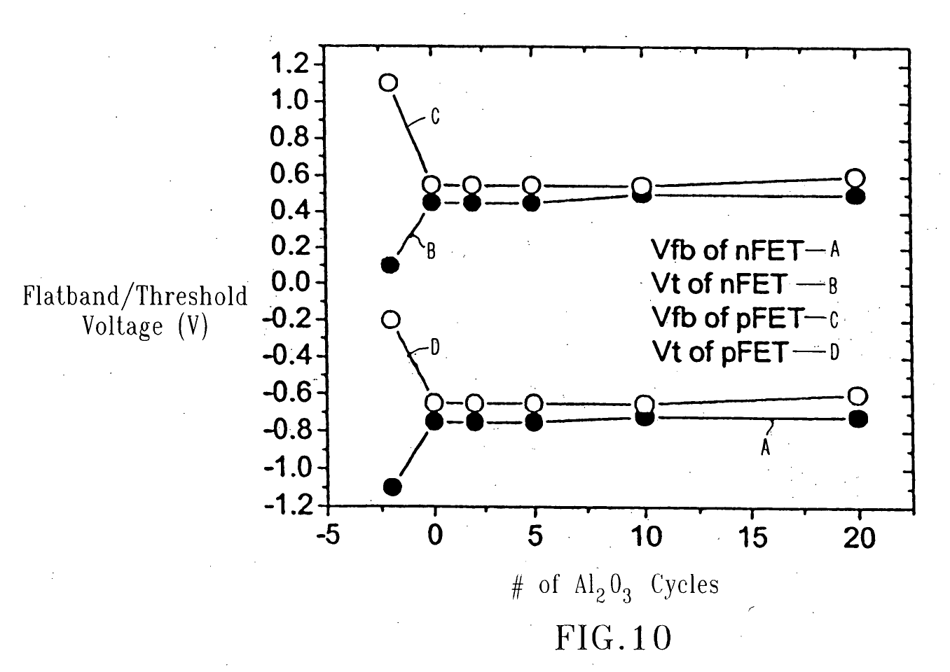

The data in FIG. 8 shows the capacitance voltage characteristics of a control SiO₂ nFET and of nFETs with hafnium silicate (20%) without (curve A) and with 2 (curve B), 5 (curve C), 10 (curve D) and 20 (curve E) cycles of Al₂O₃ as a cap layer on the hafnium silicate deposited prior to poly-Si deposition. As can be seen, a large shift was observed when replacing SiO2 with the hafnium silicate high-k dielectric. The decrease in accumulation and inversion capacitance is apparent from the data, proving that Al₂O₃ material is indeed contributing to the total gate capacitance (see FIG. 7). However, flatband and threshold voltage do not significantly change with cap layer thickness as summarized in FIG. 10.

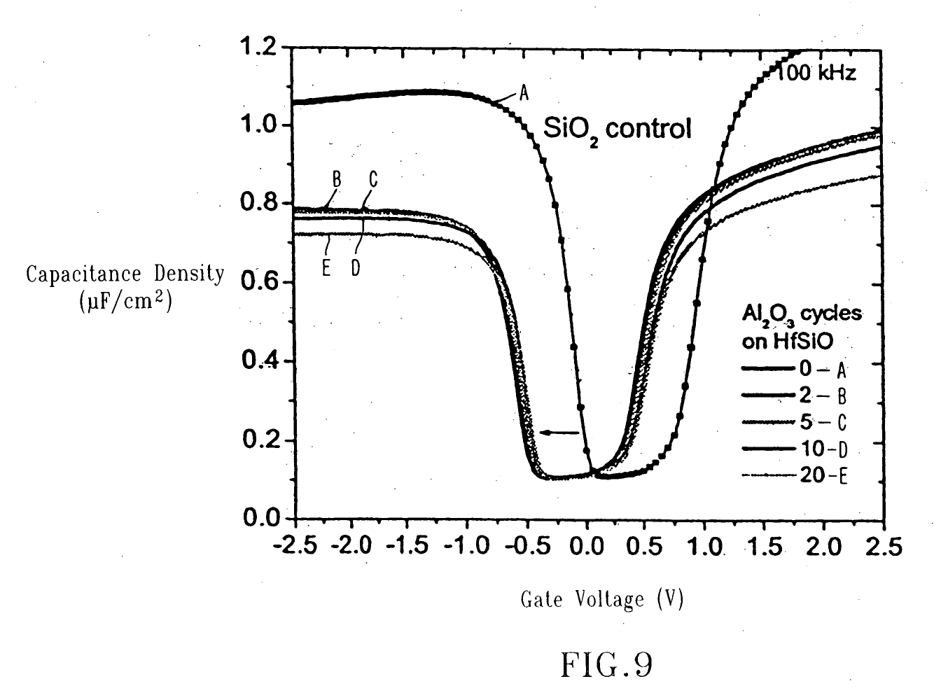

The data in FIG. 9 shows the capacitance voltage characteristics of a control SiO₂ pFET and of pFETs with hafnium silicate (20%) without (curve A) and with 2 (curve B), 5 (curve C), 10 (curve D) and 20 (curve E) cycles of Al₂O₃ as a cap layer on the hafnium silicate deposited prior to poly-Si deposition. As in FIG. 8, a large shift was observed when replacing SiO₂ with the hafnium silicate high-k dielectric. The decrease in accumulation and inversion capacitance is apparent from the data, proving that Al₂O₃ material is indeed contributing to the total gate capacitance (see FIG. 7). However, flatband and threshold voltage do not significantly change with cap layer thickness, as summarized in FIG. 10.

The data in FIG. 10 summarizes the flatband voltages and threshold voltages extracted from the data shown in FIGS. 8-9 As can be seen, a large change of the voltages was observed when replacing SiO₂ with the hafnium-silicate dielectric, however, no change can be induced by Al₂O₃ cap layers on the hafnium silicate.

The presented data demonstrates the difficulties of replacing SiO₂ as a gate dielectric with hafnium silicate because the flatband and threshold voltages of the devices exhibit unacceptable values. The data also demonstrates that the use of arbitrary capping layers does not improve the flatband voltage or threshold voltage towards the ideal values observed with the control devices. In addition to SiN caps, Al₂O₃ caps will not help in the fabrication of FETs with hafnium based gate dielectrics. Finding a suitable cap layer is not a trivial matter.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

1. A complementary metal oxide semiconductor (CMOS) structure comprising:
a semiconductor substrate having source and drain diffusion regions located therein, said source and drain diffusion regions are separated by a device channel; and
a gate stack located on top of said device channel, said gate stack comprising a high k gate dielectric, an insulating interlayer and a Si-containing gate conductor, said insulating interlayer is located between said high k gate dielectric and said Si-containing gate conductor and is capable of stabilizing the structure's threshold voltage and flatband voltage to a targeted value.

2. The CMOS structure of claim 1 wherein said semiconductor substrate comprises Si, Ge, SiGe, SiC, SiGeC, Ga, Gas, InAs, InP, other III/V or II/VI compound semiconductors, organic semiconductors, or layered semiconductors.

3. The CMOS structure of claim 1 wherein said semiconductor substrate comprises Si, SiGe, silicon-on-insulators or silicon germanium-on-insulators.

4. The CMOS structure of claim 1 wherein said semiconductor substrate is doped with an n-type dopant, a p-type dopant or both.

5. The CMOS structure of claim 1 wherein said high k gate dielectric comprises an oxide, a nitride, an oxynitride or a silicate.

6. The CMOS structure of claim 1 wherein said high k gate dielectric comprises HfO₂, ZrO₂, Al₂O₃, TiO₂, La₂O₃, SrTiO₃, LaAlO₃, Y₂O₃, SiO₂, nitrided SiO₂ or silicates, nitrides or nitrided silicates thereof

7. The CMOS structure of claim 1 wherein said insulating interlayer comprises an insulating metal nitride.

8. The CMOS structure of claim 7 wherein said metal nitride further comprises oxygen.

9. The CMOS structure of claim 1 wherein said insulating interlayer comprises aluminum nitride (AlN), aluminum oxynitride (AlOₓN_{y}), boron nitride (BN), boron oxynitride (BOₓN_{y}), gallium nitride (GaN), gallium oxynitride (GaON), indium nitride (InN), indium oxynitride (InON) or combinations thereof

10. The CMOS structure of claim 1 wherein said insulating interlayer comprises AlN or AlOₓN_{y}.

11. The CMOS structure of claim 1 wherein said insulating interlayer has a thickness from about 1 to about 25 Å.

12. The CMOS structure of claim 1 wherein said Si-containing gate conductor comprises Si or a SiGe alloy.

13. The CMOS structure of claim 1 wherein said Si-containing gate conductor comprises polysilicon that is doped with at least boron.

14. A complementary metal oxide semiconductor (CMOS) structure comprising:
a semiconductor substrate having source and drain diffusion regions located therein, said source and drain diffusion regions are separated by a device channel; and
a gate stack located on top of said device channel, said gate stack comprising a hafnium-containing high k gate dielectric, an aluminum nitride-containing insulating interlayer and a Si-containing gate conductor, said aluminum nitride-containing insulating interlayer is located between said hafnium-containing high k gate dielectric and said Si-containing gate conductor and is capable of stabilizing the structure's threshold voltage and flatband voltage to a targeted value.

15. The CMOS structure of claim 14 wherein said semiconductor substrate comprises Si, Ge, SiGe, SiC, SiGeC, Ga, Gas, InAs, InP, other III/V or II/VI compound semiconductors, organic semiconductors, or layered semiconductors.

16. The CMOS structure of claim 14 wherein said semiconductor substrate comprises Si, SiGe, silicon-on-insulators or silicon germanium-on-insulators.

17. The CMOS structure of claim 14 wherein said semiconductor substrate is doped with an n-type dopant, a p-type dopant or both.

18. The CMOS structure of claim 14 wherein said aluminum nitride-containing insulating interlayer further comprises oxygen.

19. The CMOS structure of claim 14 wherein said hafnium-containing high k gate dielectric is HfO₂, hafnium silicate or hafnium silicon oxynitride.

20. The CMOS structure of claim 14 wherein said aluminum nitride-containing insulating interlayer has a thickness from about 1 to about 25 Å.

21. The CMOS structure of claim 14 wherein said Si-containing gate conductor comprises Si or a SiGe alloy.

22. The CMOS structure of claim 14 wherein said Si-containing gate conductor comprises polysilicon that is doped with at least boron.

23. A method of forming a complementary metal oxide semiconductor (CMOS) structure having improved threshold voltage and flatband voltage stability comprising the step of:
providing a gate stack comprising a high k gate dielectric, an insulating interlayer and a Si-containing gate conductor on a semiconductor substrate, said insulating interlayer is located between said high k gate dielectric and said Si-containing gate conductor; and
applying a bias to said gate stack, whereby said insulating interlayer stabilizes the structure's threshold voltage and flatband voltage to a targeted value.

24. The method of claim 23 wherein said providing said gate stack comprises depositing blanket layers of said high k dielectric, said insulating interlayer and said Si-containing gate conductor atop a semiconductor substrate; and patterning said blanket layers by lithography and etching.

25. The method of claim 23 wherein after said providing said gate stack, source and drain diffusion regions are formed in said semiconductor substrate abutting the gate stack.

26. The method of claim 23 wherein said insulating interlayer is formed by deposition or thermal growing.

27. The method of claim 23 wherein said insulating interlayer comprises an insulating metal nitride.

28. The method of claim 27 wherein said metal nitride further comprises oxygen.

29. The method of claim 23 wherein said insulating interlayer comprises aluminum nitride (AlN), aluminum oxynitride (AlOₓN_{y}), boron nitride (BN), boron oxynitride (BOₓN_{y}), gallium nitride (GaN), gallium oxynitride (GaON) indium nitride (InN), indium oxynitride (InON) or combinations thereof.

30. The method of claim 23 wherein said insulating interlayer comprises AlN or AlOₓN_{y}.

31. The method of claim 23 wherein said high k dielectric comprises HfO₂, hafnium silicate or hafnium silicon oxynitride.

32. The method of claim 23 wherein said Si-containing gate conductor comprises Si or a SiGe alloy.
